(19) United States
(12) Patent Application Publication
(10) Pub. No.: US 2026/0324352 A1
(43) Pub. Date: Oct. 15, 2026

(54) SUBSTRATE TRANSFERRING SYSTEM AND METHOD

(71) Applicant: Gudeng Precision Industrial Co., LTD., New Taipei City (TW)

(72) Inventors: Ming-Chien Chiu, New Taipei City (TW); Yung-Chin Pan, New Taipei City (TW); Po-Ting Lee, New Taipei City (TW)

(21) Appl. No.: 19/643,026

(22) Filed: Apr. 9, 2026

Related U.S. Application Data
(60) Provisional application No. 63/787,007, filed on Apr. 11, 2025.

(51) Int. Cl. H10P 72/30

(52) U.S. Cl. CPC H10P 72/3411; H10P 72/3402

(57) ABSTRACT

A substrate transferring system and method for transferring a substrate between a first-type container and a second-type container include a first transferring mechanism, a second transferring mechanism, and a substrate transferring platform. The first transferring mechanism is disposed adjacent to the first-type container and is configured to pick and place the substrate and/or a carrier tray carrying the substrate from and into the first-type container. The second transferring mechanism is disposed adjacent to the second-type container and is configured to pick and place the substrate from and into the second-type container. The substrate transferring platform is disposed between the first transferring mechanism and the second transferring mechanism and is configured to receive at least the substrate to facilitate a handover of the substrate between the first transferring mechanism and the second transferring mechanism.

### RELATED APPLICATIONS

This application claims priority to U.S. Provisional Patent Application, No. U.S. 63/787,007, by CHIU, et al., titled “SUBSTRATE TRANSFERRING METHOD AND SYSTEM,” filed on Apr. 11, 2025, which is hereby incorporated by reference in their entirety.

### BACKGROUND OF THE INVENTION

### Technical Field

The present invention relates to a substrate transferring system and method. More particularly, the present invention relates to a substrate transferring system and method adapted for use in the semiconductor field.

### Description of Related Art

In the semiconductor industry, a wide variety of substrates are used in the fabricating process related to semiconductor components. A substrate container is used to accommodate the substrates and protect them from collisions and environmental pollution.

In response to the technological advancements in the semiconductor industry, substrate sizes are becoming larger to reduce costs. Currently, the transportation of large substrates relies on carrier trays, which are used to carry and support the substrates, preventing deformation or bending during transportation. In the field of semiconductor fabrication, different types of substrate containers are used to transport the substrates between fabrication plants. Due to variations in container types and designs, transferring the substrates between different types of substrate containers is challenging. The solution for automatically transferring the substrates is still absent in the industry. As a result, the transferring operation needs to be performed manually and requires significant labor, which is not only time-consuming but also reduces the overall efficiency of semiconductor processes. Additionally, the manual operations can easily damage the substrates.

Therefore, there exists a need for an effective and safe solution for transferring substrates between different types of substrate containers.

### SUMMARY

In view of the above-mentioned problems, the present invention provides a substrate transferring system and method, which uses a substrate transferring platform to temporarily support a substrate, to facilitate different transferring mechanisms to pick and place the substrate from and into different types of substrate containers, thereby avoiding various problems caused by known manual transfer.

According to one aspect of the invention, a substrate transferring system for transferring a substrate between a first-type container and a second-type container is provided. The substrate transferring system includes a first transferring mechanism, a second transferring mechanism, and a substrate transferring platform. The first transferring mechanism is disposed adjacent to the first-type container and is configured to pick and place the substrate and/or a carrier tray carrying the substrate from and into the first-type container. The second transferring mechanism is disposed adjacent to the second-type container and is configured to pick and place the substrate from and into the second-type container. The substrate transferring platform is disposed between the first transferring mechanism and the second transferring mechanism and is configured to receive at least the substrate to facilitate a handover of the substrate between the first transferring mechanism and the second transferring mechanism

In one embodiment, the first transferring mechanism is configured to transfer the substrate and/or the carrier tray between the substrate transferring platform and the first-type container, and the second transferring mechanism is configured to transfer the substrate between the substrate transferring platform and the second-type container.

In another embodiment, the substrate transferring platform is further configured to separate the substrate from the carrier tray to support the substrate above the carrier tray.

In a further embodiment, the first transferring mechanism is configured to lift the carrier tray such that the substrate is again carried by the carrier tray, thereby allowing the substrate and the carrier tray to be transferred together to the first-type container.

In one embodiment, the substrate transferring platform includes a frame body and plural alignment units. The alignment units are pivotally connected to the frame body and are pivotable between an open state and an alignment state. The alignment units define an alignment area when in the alignment state. The first transferring mechanism is configured to transfer the substrate into the alignment area.

In another embodiment, the substrate transferring system further includes a tray placement platform configured to receive the carrier tray. The first transferring mechanism is configured to transfer the carrier tray from the tray placement platform to the first-type container or the substrate transferring platform.

According to another aspect of the invention, a substrate transferring method for transferring a substrate between a first-type container and a second-type container is provided. The substrate transferring method includes: picking or placing, by a first transferring mechanism, the substrate and/or a carrier tray carrying the substrate from or into the first-type container; receiving at least the substrate, by a substrate transferring platform, to facilitate a handover of the substrate between the first transferring mechanism and a second transferring mechanism; and picking or placing, by a second transferring mechanism, the substrate from or into the second-type container.

According to yet another aspect of the present invention, a substrate transferring method for transferring a substrate between a first-type container and a second-type container is provided. The substrate transferring method includes: transferring, by a first transferring mechanism, the substrate and/or a carrier tray carrying the substrate from the first-type container to a substrate transferring platform; and transferring, by a second transferring mechanism, the substrate from the substrate transferring platform to the second-type container.

In one embodiment, the substrate transferring method further includes: transferring, by the second transferring mechanism, the substrate from the second-type container to the substrate transferring platform; and transferring, by the first transferring mechanism, at least the substrate from the substrate transferring platform to the first-type container.

In another embodiment, the substrate and the carrier tray are transferred together by the first transferring mechanism from the first-type container to the substrate transferring platform. After the substrate and the carrier tray are transferred together to the substrate transferring platform, the substrate transferring method further includes: separating, by the substrate transferring platform, the substrate from the carrier tray to support the substrate above the carrier tray.

The substrate transferring system and method according to the embodiments of the present invention transfer the substrate from the first-type container to the substrate transferring platform by the first transferring mechanism, and transfer the substrate from the substrate transferring platform into the second-type container by the second transferring mechanism, thereby achieving fast, efficient, and safe substrate transferring. As a result, the problems of conventional manual transferring, which requires massive labor and time and reduces overall process efficiency, can be solved. Additionally, the risk of damaging the substrate caused by the transferring process can also be significantly reduced.

### BRIEF DESCRIPTION OF DRAWINGS

The present invention can be more fully understood by reading the following detailed description of the embodiment, with reference made to the accompanying drawings as follows.

FIG. 1 is a functional block diagram of a substrate transferring system according to one embodiment of the present invention.

FIG. 2 is a schematic diagram of a first-type container.

FIG. 3 is a schematic diagram of the first-type container and a door opening mechanism.

FIG. 4 is a schematic diagram of the first-type container after a door is removed.

FIG. 5 is a schematic diagram illustrating the substrates and the carrier trays stacked in the first-type container.

FIG. 6 is a schematic diagram of a first transferring mechanism according to one embodiment of the present invention.

FIG. 7 is a schematic diagram of a corresponding position between a substrate and a carrier tray.

FIG. 8 is a schematic diagram of an exclusion area on a carrier tray according to one embodiment of the present invention.

FIG. 9a is a schematic diagram of an exclusion area on a carrier tray according to another embodiment of the present invention.

FIG. 9b is a schematic diagram of an exclusion area on a carrier tray according to yet another embodiment of the present invention.

FIG. 10 illustrates a method flowchart of a substrate transferring method according to one embodiment of the present invention.

FIG. 11 illustrates a method flowchart of a substrate transferring method according to another embodiment of the present invention.

FIGS. 12a to 12e are schematic diagrams illustrating a process of the first transferring mechanism transferring the substrate to the substrate transferring platform.

FIGS. 13a to 13c are schematic diagrams illustrating a process of the second transferring mechanism transferring the substrate into the second-type container.

FIGS. 14a to 14e are schematic diagrams illustrating a process of the first transferring mechanism transferring the carrier tray to the tray placement platform.

FIG. 15 illustrates a method flowchart of further steps of the substrate transferring method.

FIG. 16 is a schematic diagram of a substrate transferring platform according to another embodiment of the present invention.

FIG. 17 is a schematic diagram of a substrate transferring platform of a substrate transferring system according to another embodiment of the present invention.

FIG. 18 illustrates a method flowchart of a substrate transferring method according to another embodiment of the present invention.

FIGS. 19a to 19c are schematic diagrams illustrating a process of the first transferring mechanism transferring the substrate and the carrier tray to the substrate transferring platform.

FIG. 20 is a schematic diagram illustrating the separation of the substrate from the carrier tray.

FIGS. 21a to 21c are schematic diagrams illustrating a process of the second transferring mechanism taking the substrate out from the substrate transferring platform.

FIG. 22 illustrates a method flowchart of further steps of the substrate transferring method.

FIGS. 23a to 23e are schematic diagrams illustrating a process of the second transferring mechanism transferring the substrate back to the substrate transferring platform.

FIGS. 24a to 24b are schematic diagrams illustrating a process of the first transferring mechanism lifting the carrier tray.

FIGS. 25a to 25b are schematic diagrams illustrating a process of the first transferring mechanism transferring the substrate and the carrier tray into the first-type container.

### DETAILED DESCRIPTION

The substrate transferring system and method according to the embodiments of the present invention use a substrate transferring platform to temporarily support the substrate. The substrate can therefore be picked and placed from and into different types of substrate containers by different transferring mechanisms. The first transferring mechanism transfers the substrate from a first-type container to the substrate transferring platform, and a second transferring mechanism transfers the substrate from the substrate transferring platform into a second-type container. By means of the technical solutions of the embodiments of the present invention, fast, efficient, and safe substrate transferring can be achieved. The problems of conventional manual transferring requiring massive labor and time and reducing process efficiency can be solved. In addition, the risk of damaging the substrate by the transferring process can also be significantly reduced.

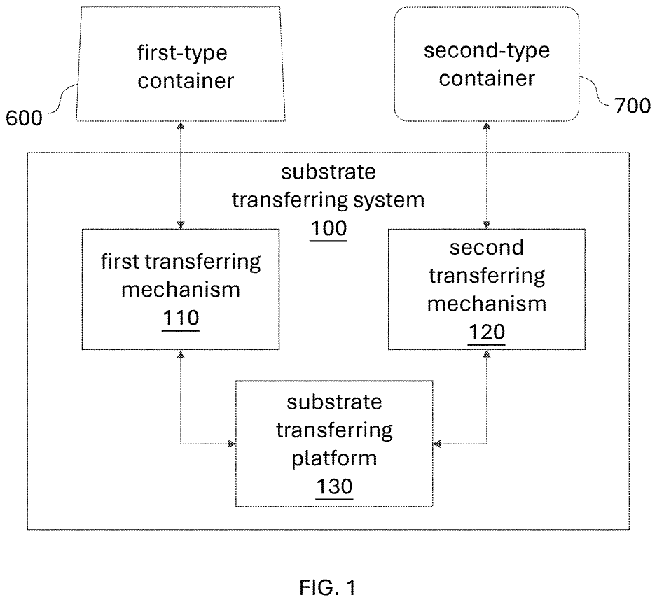

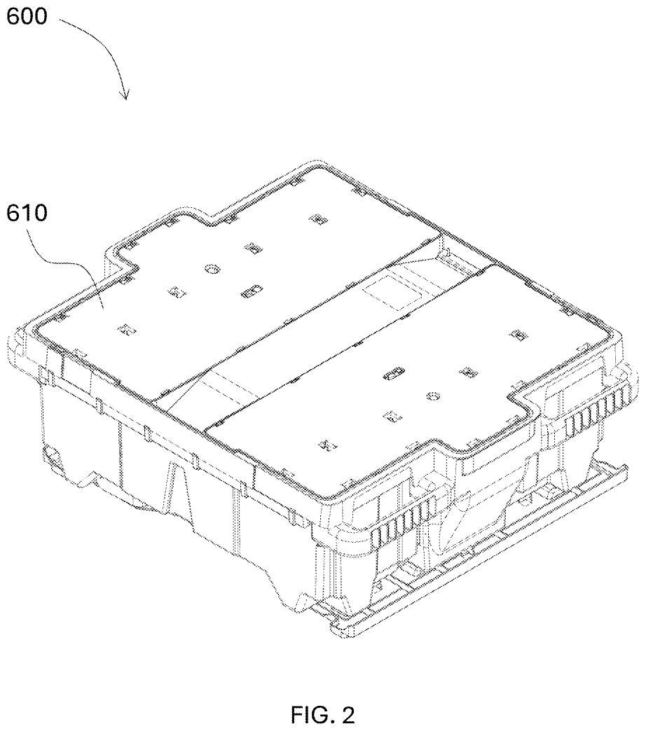

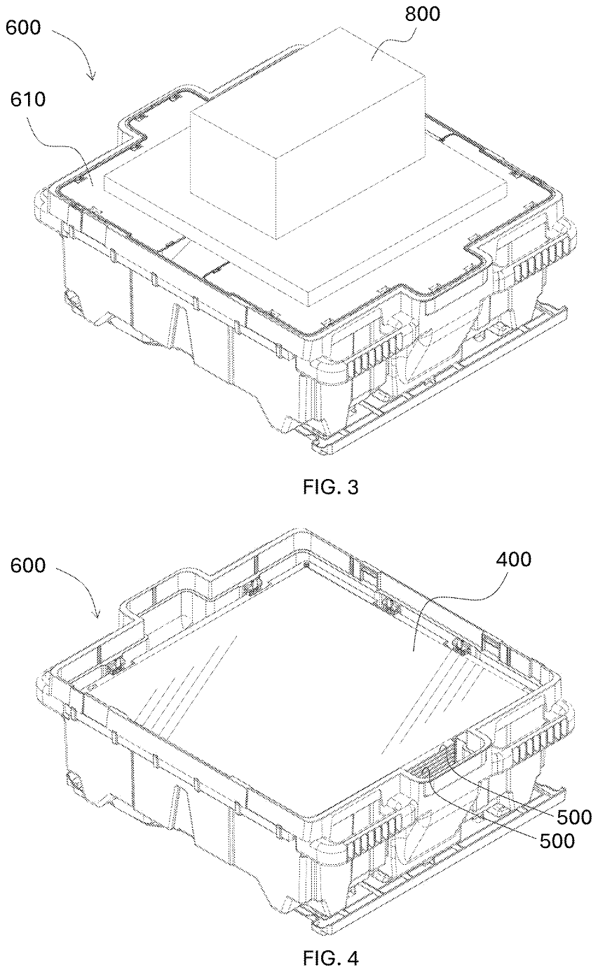

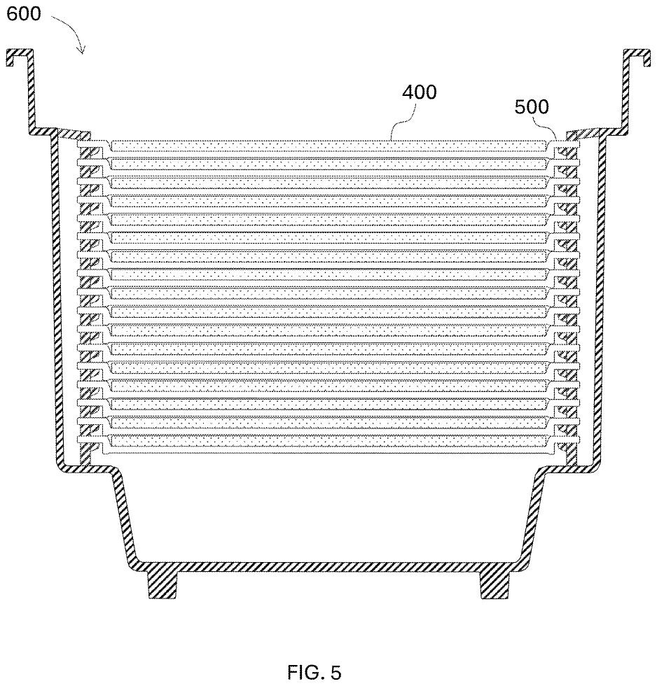

Please refer to FIGS. 1 to 4 at the same time. FIG. 1 is a functional block diagram of a substrate transferring system according to one embodiment of the present invention. FIG. 2 is a schematic diagram of a first-type container. FIG. 3 is a schematic diagram of the first-type container and a door opening mechanism. FIG. 4 is a schematic diagram of the first-type container after a door is removed. The substrate transferring system 100 of the present embodiment is used for transferring a substrate 400 between a first-type container 600 and a second-type container 700. The substrate transferring system 100 includes: a first transferring mechanism 110, a second transferring mechanism 120, and a substrate transferring platform 130. The first transferring mechanism 110 is disposed adjacent to the first-type container 600 and is configured to pick and place the substrate 400 and/or a carrier tray 500 carrying the substrate 400 from and into the first-type container 600. The second transferring mechanism 120 is disposed adjacent to the second-type container 700 and is configured to pick and place the substrate 400 from and into the second-type container 700. The substrate transferring platform 130 is disposed between the first transferring mechanism 110 and the second transferring mechanism 120 and is configured to receive at least the substrate 400 to facilitate a handover of the substrate 400 between the first transferring mechanism 110 and the second transferring mechanism 120.

Moreover, the first-type container 600, for example, has a door 610. When the door 610 is removed by a door opening mechanism 800, the substrate 400 and the carrier tray 500 accommodated inside the first-type container 600 are exposed. The first transferring mechanism 110 is used for transferring the substrate 400 and/or the carrier tray 500 between the substrate transferring platform 130 and the first-type container 600. The second transferring mechanism 120 is used for transferring the substrate 400 between the substrate transferring platform 130 and the second-type container 700. In one embodiment, the first transferring mechanism 110 is used for sequentially and separately transferring the substrate 400 and the carrier tray 500. In a different embodiment, the first transferring mechanism 110 is used for transferring the carrier tray 500 and the substrate 400 carried thereon together.

The substrate transferring system 100 of the present embodiment uses the substrate transferring platform 130 to temporarily support the substrate 400, which facilitates a handover the substrate 400 between the first transferring mechanism 110 and the second transferring mechanism 120. Therefore, the substrate 400 can be transferred back and forth between the first-type container 600 and the second-type container 700.

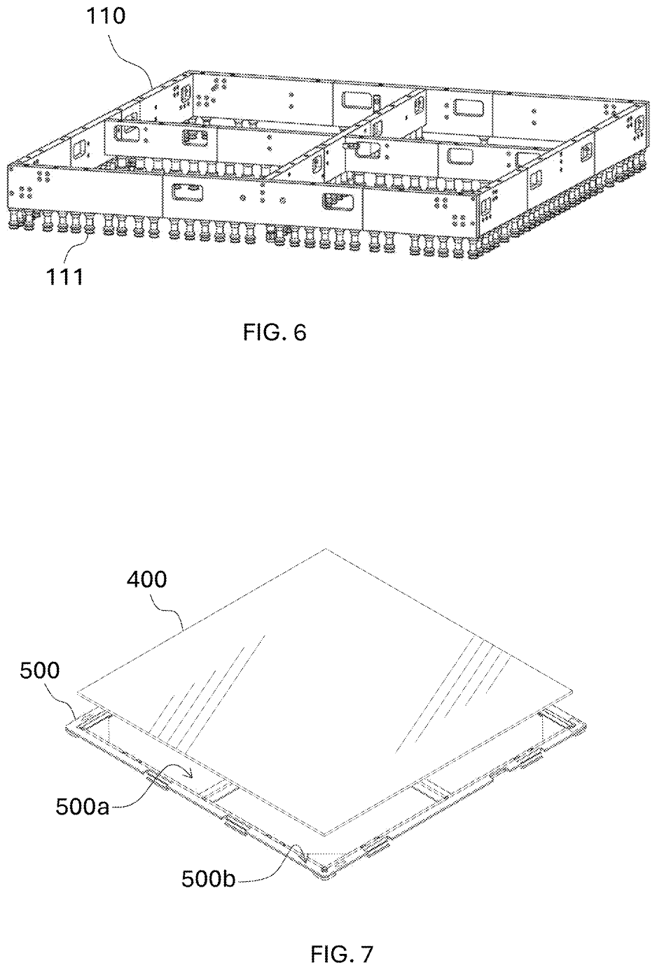

The first-type container 600 and the second-type container 700 are two different types of substrate containers. For example, as shown in FIGS. 2 to 4, the first-type container 600 is a top-opening substrate carrier, in which, plural substrates 400 are sequentially disposed in the first-type container 600 in a vertically stacked manner. Please refer to FIGS. 1 to 5 at the same time. FIG. 5 is a schematic diagram illustrating the substrates and the carrier trays stacked in the first-type container. The substrates 400 are carried on the carrier trays 500 and are sequentially stacked in the first-type container 600. After the door 610 is removed, the first transferring mechanism 110 can sequentially pick the substrate 400 and/or the carrier tray 500 along a vertical direction, thereby transferring the substrate 400 in this manner. In one embodiment, the first transferring mechanism 110 sequentially picks the substrate 400 and the carrier tray 500 in the vertical direction; in different embodiments, the first transferring mechanism 110 directly picks the carrier tray 500 in the vertical direction, thereby transferring the carrier tray 500 out of the first-type container 600 together with the substrate 400 carried thereon.

The second-type container 700 is, for example, a front-opening substrate carrier. The substrate 400 is transferred into the second-type container 700 by the second transferring mechanism 120 along a horizontal direction. The substrate 400 is directly supported by a support structure inside the second-type container 700, so the carrier tray 500 is not required in the second-type container 700.

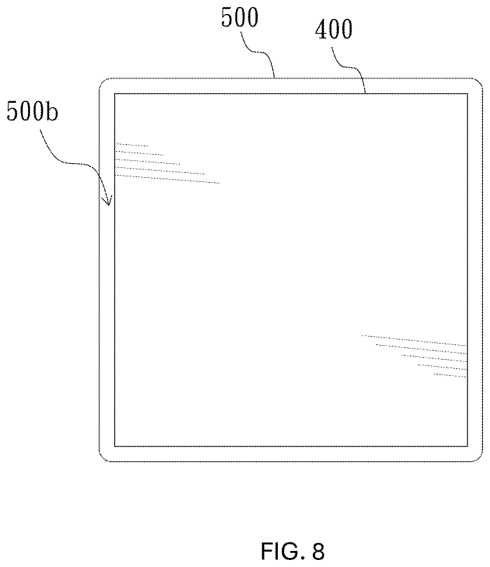

The first transferring mechanism 110 and the second transferring mechanism 120 are two different types of transferring mechanisms. The purpose is to pick and place the substrate 400 from and into the first-type container 600 and the second-type container 700 of different types. Please refer to FIG. 6, which is a schematic diagram of a first transferring mechanism according to one embodiment of the present invention. The first transferring mechanism 110 is, for example, an automated pick-and-place device equipped with vacuum nozzles 111. The first transferring mechanism 110 is used to pick and place the substrate 400 and/or the carrier tray 500 from and into the first-type container 600 in the vertical direction. In one embodiment, these vacuum nozzles 111 are at least partially retractable nozzles, which can adjust their heights respectively in order to match the height of the substrate 400 or the carrier tray 500 in the vertical direction.

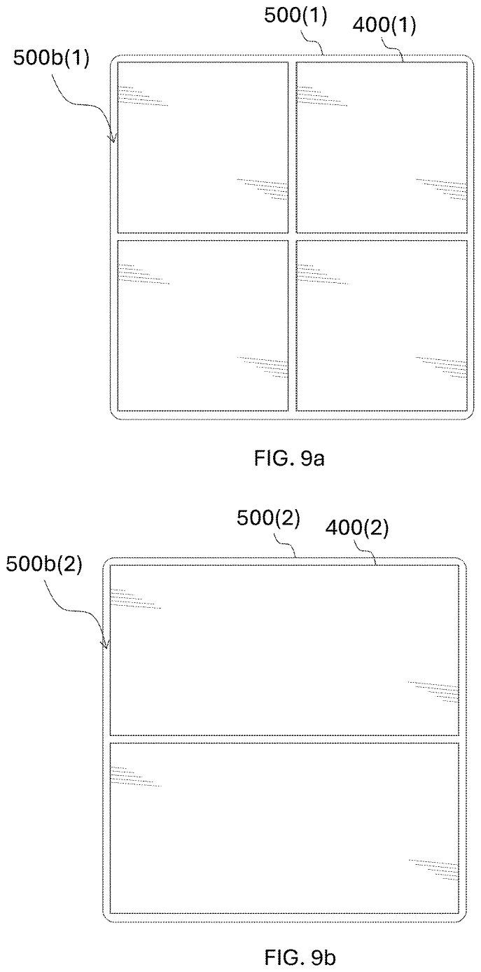

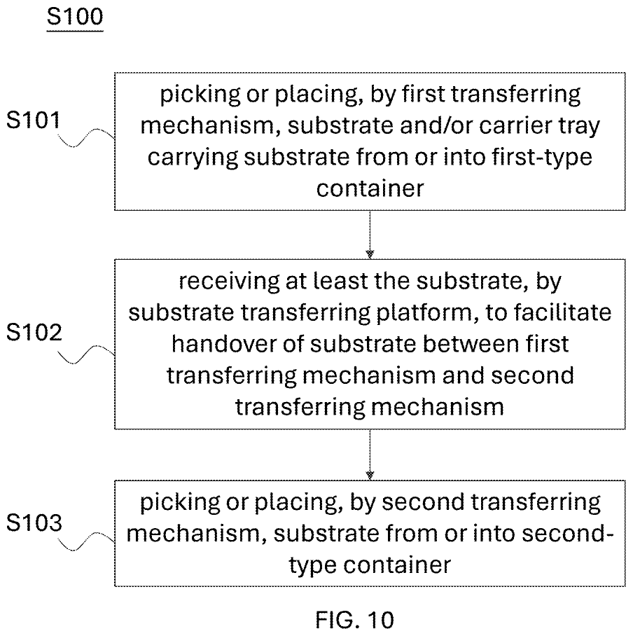

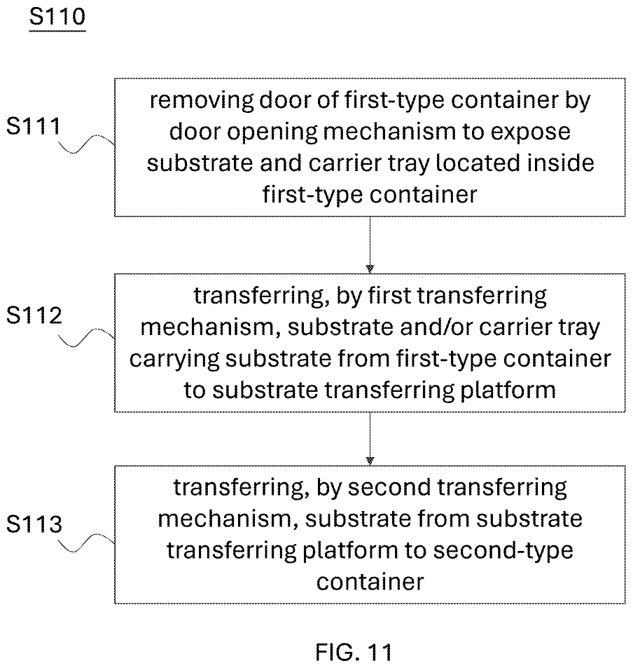

Please refer to FIGS. 7 to 9b. FIG. 7 is a schematic diagram of a corresponding position between a substrate and a carrier tray. FIG. 8 is a schematic diagram of an exclusion area on a carrier tray according to one embodiment of the present invention. FIG. 9a is a schematic diagram of an exclusion area on a carrier tray according to another embodiment of the present invention. FIG. 9b is a schematic diagram of an exclusion area on a carrier tray according to yet another embodiment of the present invention. The carrier tray 500 has a substrate area 500a and an exclusion area 500b thereon. The substrate area 500a is an area used to support the substrate 400 and overlaps with the substrate 400, and the exclusion area 500b surrounds the substrate area 500a. The carrier tray 500 can carry one or more substrates 400 corresponding to different actual product requirements. As shown in FIG. 8, the carrier tray 500 carries one substrate 400, and the exclusion area 500b surrounds the substrate 400. The carrier tray 500(1) of FIG. 9a carries four substrates 400(1), and the exclusion area 500b(1) surrounds these substrates 400(1). The carrier tray 500(2) shown in FIG. 9b is used to carry two substrates 400(2), and the exclusion area 500b(2) surrounds these substrates 400(2). The vacuum nozzles 111 on the first transferring mechanism 110 are arranged in a manner corresponding to the substrate area 500a and the exclusion area 500b. In this arrangement, the substrate 400 or the carrier tray 500 can be selectively picked and placed by activating the vacuum nozzles 111 at different locations.

The second transferring mechanism 120 is, for example, a robotic arm movable at least in the horizontal direction (lateral direction), thereby allowing the substrate 400 to horizontally enter or leave the second-type container 700. The mechanical design and the type of the second transferring mechanism 120 are not particularly limited in the present invention.

In one embodiment, the substrate transferring platform 130 is configured to separate the substrate 400 from the carrier tray 500, so that the substrate 400 is supported above the carrier tray 500. The first transferring mechanism 110 is further used to lift the carrier tray 500 such that the substrate 400 is again carried by the carrier tray 500, which allows the substrate 400 and the carrier tray 500 to be subsequently transferred together to the first-type container 600. In the present embodiment, the substrate transferring platform 130 includes a frame body and plural alignment units respectively pivotally connected to the frame body and pivotable between an open state and an alignment state. When the alignment units are in the alignment state, an alignment area is defined. The first transferring mechanism 110 is used for transferring the substrate 400 into the alignment area. The related technical features will be detailed later in conjunction with the substrate transferring method of the embodiments of the present invention.

In addition, the substrate transferring system 100 of this embodiment optionally includes a tray placement platform configured to receive the carrier tray 500. The first transferring mechanism 110 is used for transferring the carrier tray 500 from the tray placement platform to the first-type container 600. The related technical features will be detailed later in conjunction with the substrate transferring method of the embodiments of the present invention.

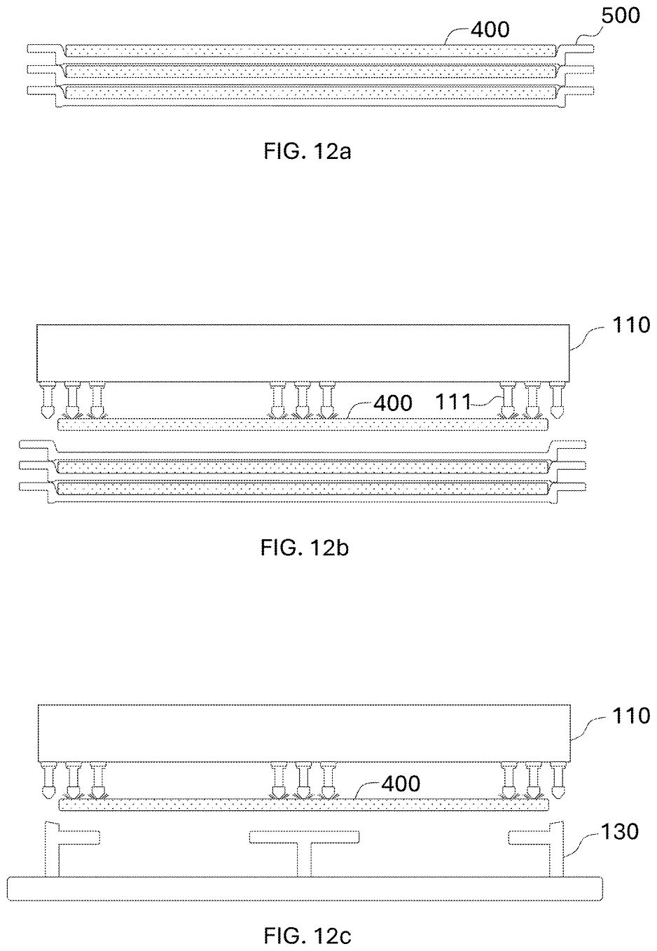

The detailed description now directs to a substrate transferring method according to one embodiment of the present invention. Please refer to FIG. 10, which illustrates a method flowchart of a substrate transferring method according to one embodiment of the present invention. The substrate transferring method S100 is used for transferring a substrate between a first-type container and a second-type container, and the substrate transferring method includes the following steps: picking or placing, by a first transferring mechanism, the substrate and/or a carrier tray carrying the substrate from or into the first-type container (step S101); receiving at least the substrate, by a substrate transferring platform, to facilitate a handover of the substrate between the first transferring mechanism and a second transferring mechanism (step S102); and picking or placing, by the second transferring mechanism, the substrate from or into the second-type container (step S103).

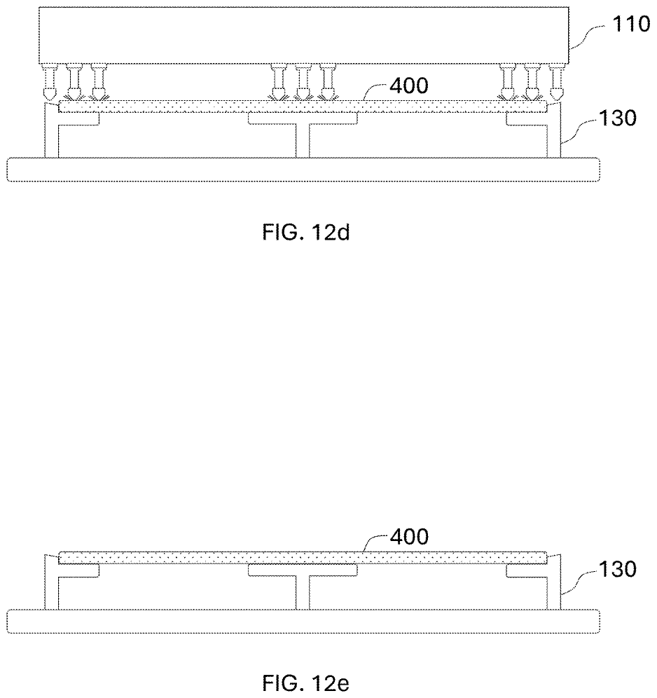

In order to more clearly elaborate the technical features of this embodiment, the substrate transferring method is described in conjunction with the aforementioned substrate transferring system 100 according to FIGS. 1 to 5. Similar components are denoted by the same reference numbers. Please refer to FIG. 11, which illustrates a method flowchart of a substrate transferring method according to another embodiment of the present invention. The substrate transferring method S110 of this embodiment is used for transferring a substrate 400 between a first-type container 600 and a second-type container 700, and includes the following steps.

First, in step S111, the door 610 of the first-type container 600 is removed by the door opening mechanism 800 to expose the substrate 400 and the carrier tray 500 located inside the first-type container 600. At this time, the substrate 400 is carried on the carrier tray 500.

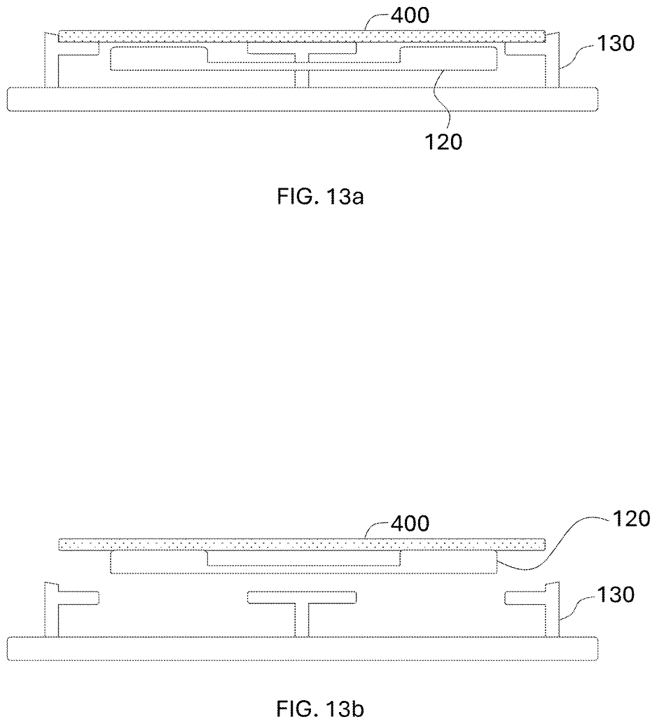

Next, in step S112, the substrate 400 is transferred to the substrate transferring platform 130 by the first transferring mechanism 110. In one embodiment, the substrate 400 is independently and directly transferred (without transferred with the carrier tray 500) from the first-type container 600 to the second-type container 700. Please refer to FIGS. 12a to 12e, which are schematic diagrams illustrating a process of the first transferring mechanism transferring the substrate to the substrate transferring platform. In this embodiment, the first transferring mechanism 110 directly picks the substrate 400. The first transferring mechanism 110 activates the vacuum nozzles 111 corresponding to the location of the substrate 400 to directly take out the substrate 400 in a vertical direction, as shown in FIGS. 12a and 12b. Then, the substrate 400 is transferred to a position above the substrate transferring platform 130, and is moved downward and placed on the substrate transferring platform 130, as shown in FIGS. 12c and 12d. The substrate transferring platform 130 of this embodiment is configured to receive and accommodate the substrate 400. The structure of the substrate transferring platform 130 is not particularly limited in the present invention; any structure design that can achieve the effect of receiving and accommodating the substrate 400 is applicable to the present invention.

Thus, the step of transferring the substrate 400 onto the substrate transferring platform 130 is completed, as shown in FIG. 12e.

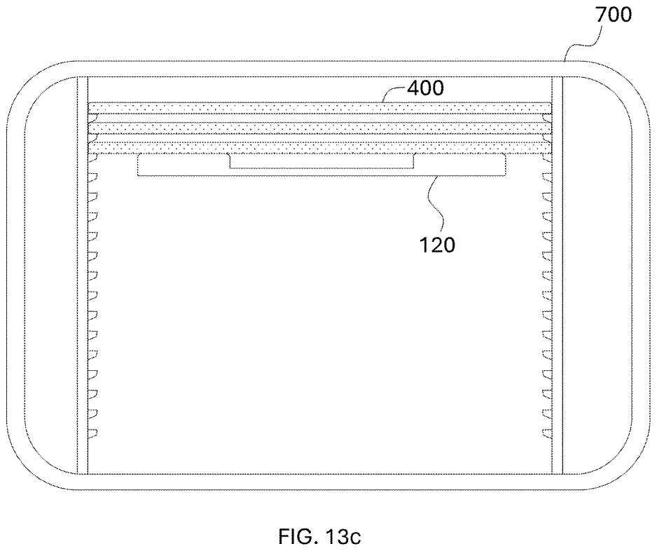

Then, in step S113, the substrate 400 is transferred from the substrate transferring platform 130 into the second-type container 700 by the second transferring mechanism 120. Please refer to FIGS. 13a to 13c, which are schematic diagrams illustrating a process of the second transferring mechanism transferring the substrate into the second-type container. In this embodiment, the second transferring mechanism 120 lifts the substrate 400 from below to raise it off the substrate transferring platform 130, as shown in FIGS. 13a and 13b. Next, the substrate 400 is transferred into the second-type container 700 such that it is supported on the support structure inside the second-type container 700, as shown in FIG. 13c. At this point, the substrate transferring method S110 for transferring the substrate 400 from the first-type container 600 to the second-type container 700 is completed.

Furthermore, the substrate transferring method S110 of this embodiment may further include a step of accommodating the carrier tray 500.

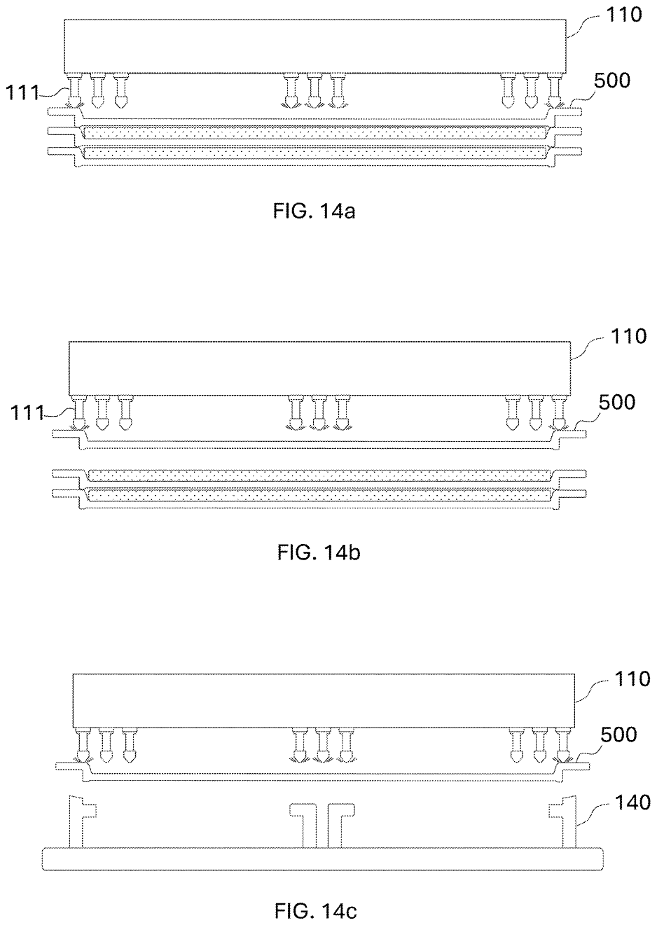

Please refer to FIGS. 14a to 14e, which are schematic diagrams illustrating a process of the first transferring mechanism transferring the carrier tray to the tray placement platform. In this embodiment, the first transferring mechanism 110 then activates the vacuum nozzles 111 corresponding to the location of the carrier tray 500 to take out the carrier tray 500 in the vertical direction, as shown in FIGS. 14a and 14b. Then, the carrier tray 500 is transferred to a position above the tray placement platform 140, and is moved downward and placed onto the tray placement platform 140, as shown in FIGS. 14c and 14d. The tray placement platform 140 of this embodiment is configured to receive and accommodate the carrier tray 500. The structure of the tray placement platform 140 is not particularly limited in the present invention; any structure which can achieve the effect of receiving and accommodating the carrier tray 500 is applicable to the present invention.

At this point, the step of transferring the carrier tray 500 onto the tray placement platform 140 by the first transferring mechanism 110 is completed, as shown in FIG. 14e.

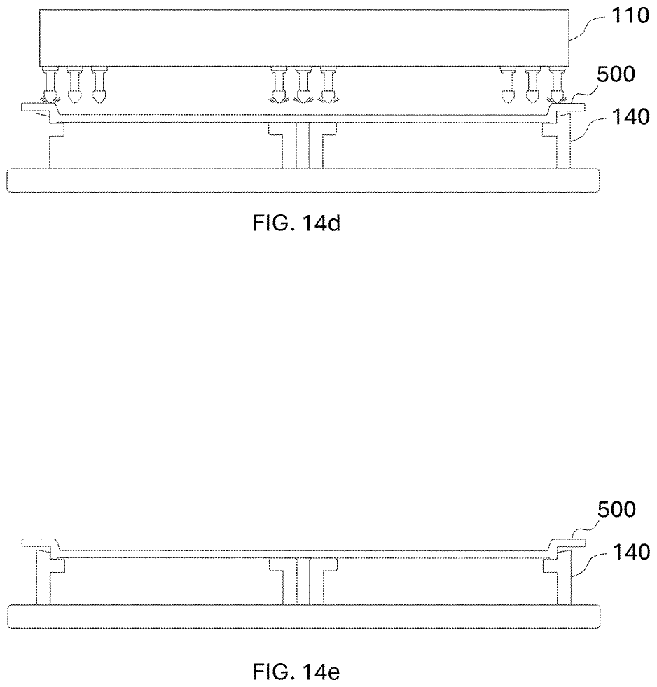

Please refer to FIG. 15, which illustrates a method flowchart of further steps of the substrate transferring method. After completing the aforementioned steps S111 to S113, the substrate transferring method S110 of this embodiment may then execute a process of transferring the substrate 400 from the second-type container 700 back to the first-type container 600.

In step S114, the substrate 400 is transferred from the second-type container 700 to the substrate transferring platform 130 by the second transferring mechanism 120.

Then, in step S115, the substrate 400 is transferred from the substrate transferring platform 130 into the first-type container 600 by the first transferring mechanism 110. Additionally, the substrate transferring method S110 may further include a step of transferring the carrier tray 500 from the tray placement platform 140 back to the first-type container 600.

According to the above description, the substrate transferring method S110 of the embodiment of the present invention enables the substrate 400 to be transferred to the second-type container 700 or transferred back to the first-type container 600 through an automated mechanism by means of the first transferring mechanism 110 and the second transferring mechanism 120, thereby achieving the effect of fast, efficient, and safe transferring of the substrate 400, and significantly reducing the risk of damaging the substrate 400.

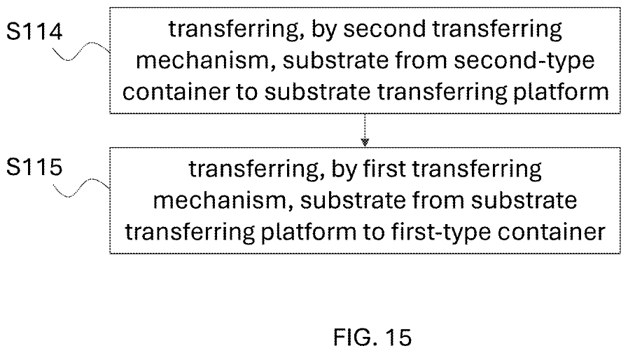

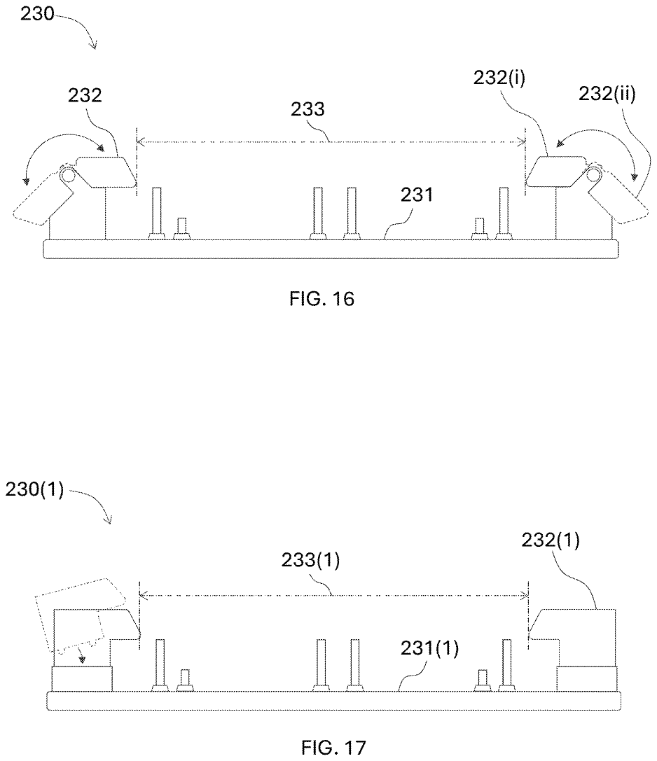

Please refer to FIG. 16, which is a schematic diagram of a substrate transferring platform according to another embodiment of the present invention. The substrate transferring platform 230 of this embodiment is configured to separate the substrate 400 from the carrier tray 500, so that the substrate 400 is supported above the carrier tray 500. The substrate transferring platform 230 includes a frame body 231 and a plurality of alignment units 232. The alignment units 232 are respectively pivotally connected to the frame body 231 and are pivotable between an open state 232(ii) and an alignment state 232(i). When the alignment units 232 are in the alignment state 232(i), an alignment area 233 is defined. The first transferring mechanism 110 is used for transferring the substrate 400 into the alignment area 233. In addition, please refer to FIG. 17, which is a schematic diagram of a substrate transferring platform of a substrate transferring system according to another embodiment of the present invention. In a different embodiment, the alignment units 232(1) of the substrate transferring platform 230(1) are disposed on the frame body 231(1) in a plug-and-assemble manner. When the alignment units 232(1) are assembled, an alignment area 233(1) is similarly defined.

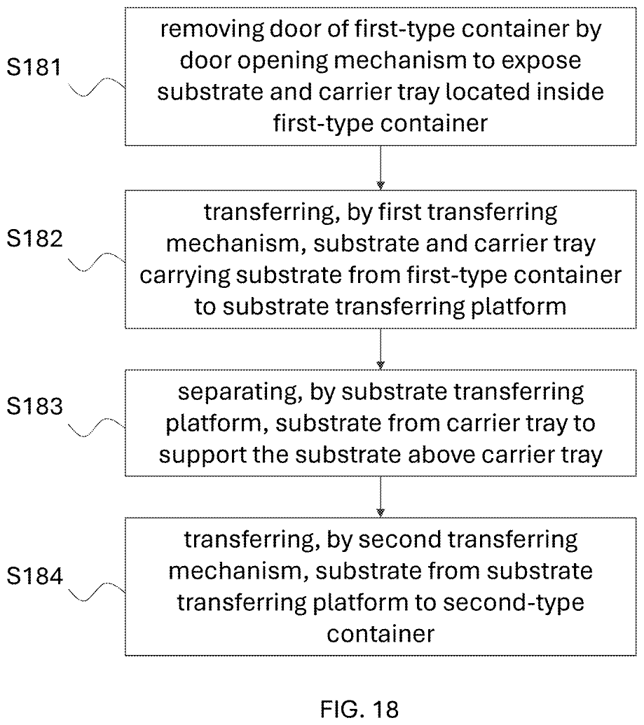

Next, a substrate transferring method according to another embodiment of the present invention is described. To more clearly show the technical features of this embodiment, the substrate transferring method is described in conjunction with the aforementioned substrate transferring system 100 according to FIGS. 1 to 5 and FIG. 16, and similar components are denoted by the same reference numbers. Please refer to FIG. 18, which illustrates a method flowchart of a substrate transferring method according to another embodiment of the present invention. The substrate transferring method S180 of this embodiment is used for transferring the substrate 400 between the first-type container 600 and the second-type container 700, and comprises the following steps.

First, in step S181, the door 610 of the first-type container 600 is removed by the door opening mechanism 800 to expose the substrate 400 and the carrier tray 500 located inside the first-type container 600. In this time, the substrate 400 is carried on the carrier tray 500.

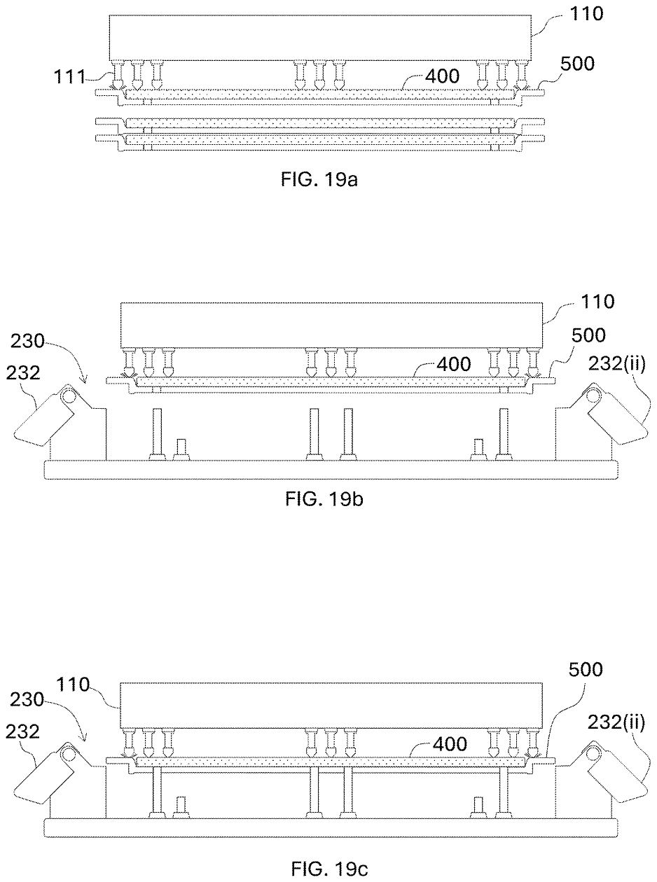

Next, in step S182, the carrier tray 500 and the substrate 400 carried thereon are transferred together to the substrate transferring platform 230 by the first transferring mechanism 110. Please refer to FIGS. 19a to 19c, which are schematic diagrams illustrating a process of the first transferring mechanism transferring the substrate and the carrier tray to the substrate transferring platform. The first transferring mechanism 110 transfers the substrate 400 by way of carried (supported) on the carrier tray 500. The first transferring mechanism 110 activates the vacuum nozzles 111 corresponding to the location of the carrier tray 500 to take out the carrier tray 500 and the substrate 400 together in the vertical direction, as shown in FIG. 19a. Then, the carrier tray 500 and the substrate 400 are transferred to a position above the substrate transferring platform 230, and are moved downward and placed on the substrate transferring platform 230. At this time, the alignment units 232 are in the open state 232(ii), as shown in FIGS. 19b and 19c.

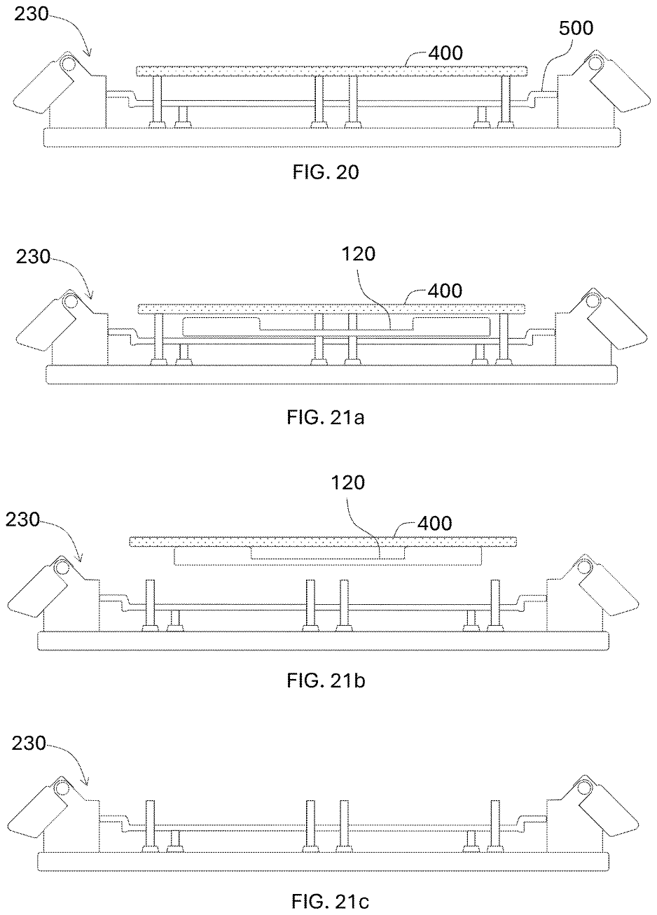

Then, in step S183, the substrate 400 is separated from the carrier tray 500 by the substrate transferring platform 230, so that the substrate 400 is supported above the carrier tray 500. Please refer to FIG. 20, which is a schematic diagram illustrating the separation of the substrate from the carrier tray. After the first transferring mechanism 110 moves away, the carrier tray 500 drops due to gravity, thereby separating the carrier tray 500 from the substrate 400 and having the substrate 400 supported on the substrate transferring platform 230.

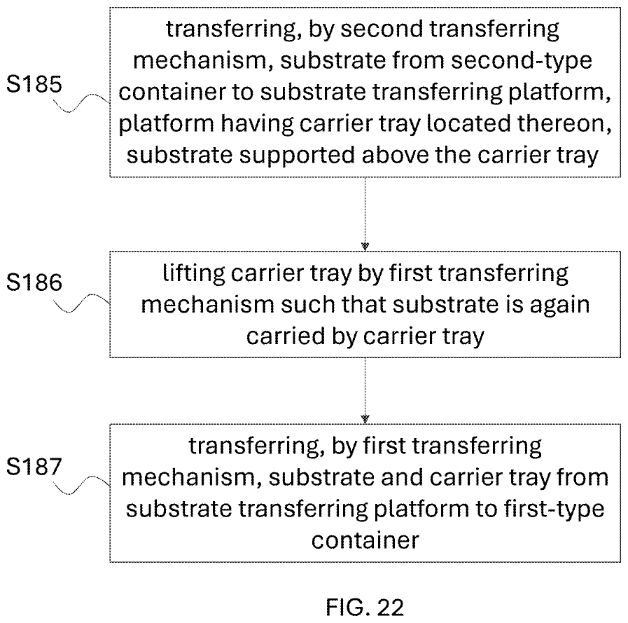

Next, in step S184, the substrate 400 is transferred from the substrate transferring platform 230 into the second-type container 700 by the second transferring mechanism 120. Please refer to FIGS. 21a to 21c, which are schematic diagrams illustrating a process of the second transferring mechanism taking the substrate out from the substrate transferring platform. The second transferring mechanism 120 lifts the substrate 400 from below to raise it off the substrate transferring platform 230, as shown in FIGS. 21a and 21b.

Then, the second transferring mechanism 120 transfers the substrate 400 into the second-type container 700. This content of this technical feature is the same as the aforementioned embodiment according to FIG. 13c and will not be repeated herein.

Thus, the substrate transferring method S180 of this embodiment is completed.

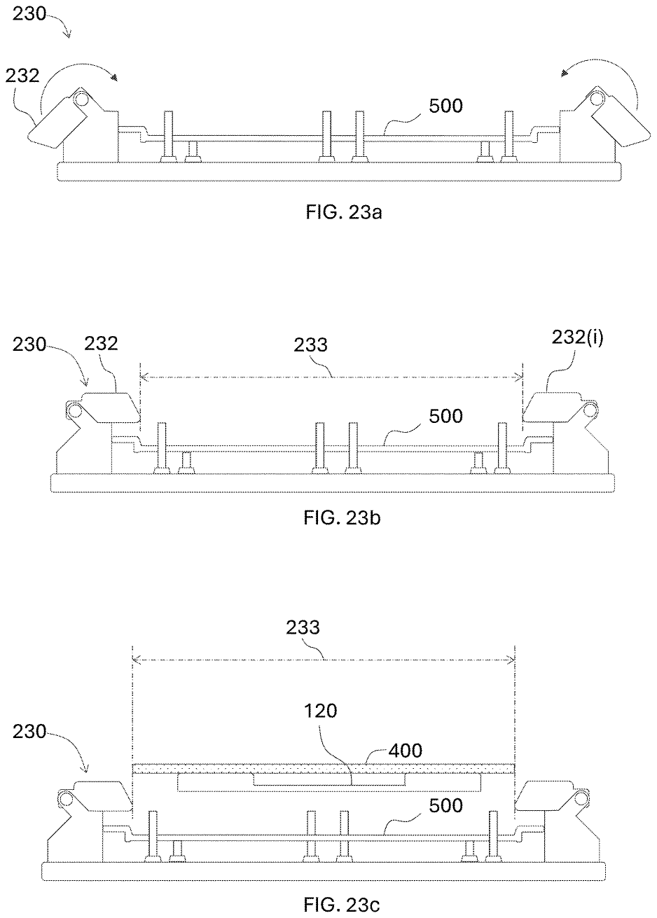

Please refer to FIG. 22, which illustrates a method flowchart of further steps of the substrate transferring method. After completing the aforementioned steps S181 to S184, the substrate transferring method S180 may further execute a step of transferring the substrate 400 from the second-type container 700 back to the first-type container 600.

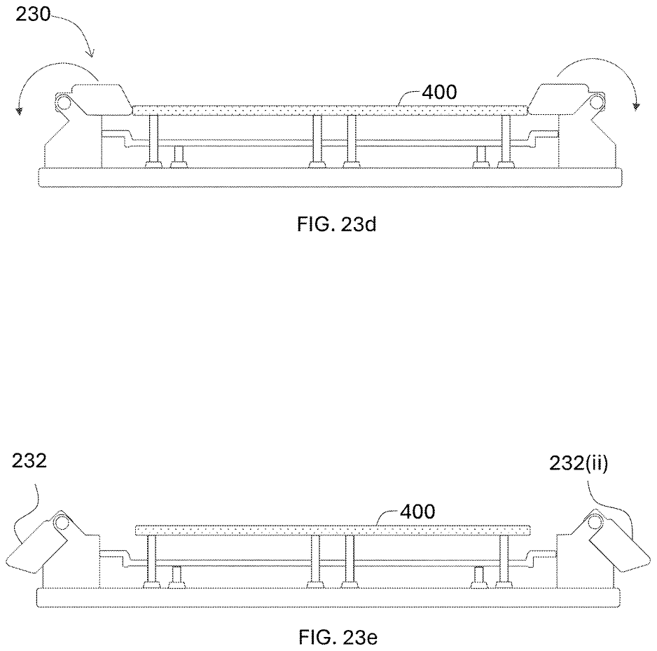

In step S185, the substrate 400 is transferred from the second-type container 700 to the substrate transferring platform 230 by the second transferring mechanism 120. In this step, the substrate transferring platform 230 has the carrier tray 500 located thereon, so the substrate 400 is transferred to be supported above the carrier tray 500. Please refer to FIGS. 23a to 23e, which are schematic diagrams illustrating a process of the second transferring mechanism transferring the substrate back to the substrate transferring platform. As shown in FIG. 23a, the carrier tray 500 is located on the substrate transferring platform 230; in an optional embodiment, the carrier tray 500 may first be transferred back to the substrate transferring platform 230 from the aforementioned tray placement platform 140 (the tray placement platform 140 is illustrated in FIGS. 14c to 14e). Then, the alignment units 232 pivot to the alignment state 232(i), thereby defining the alignment area 233, as shown in FIG. 23b. After the second transferring mechanism 120 moves the substrate 400 out of the second-type container 700, the substrate 400 is transferred to a position above the substrate transferring platform 230, and then the substrate 400 is moved downward and placed into the alignment area 233, as shown in FIGS. 23c and 23d. Thereafter, the alignment units 232 pivot to the open state 232(ii), as shown in FIG. 23 e.

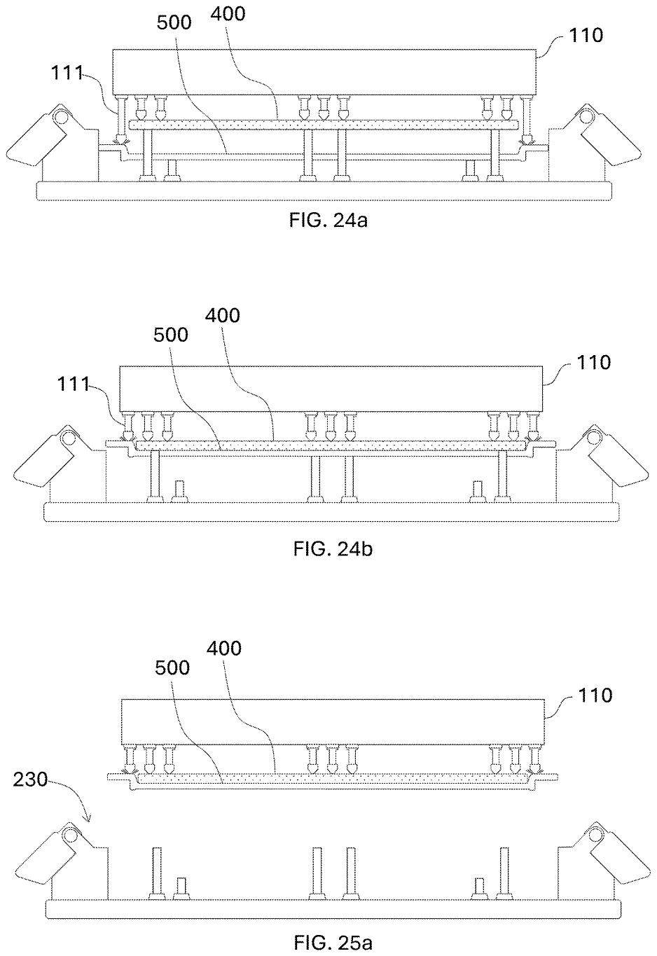

In step S186, the carrier tray 500 is lifted by the first transferring mechanism 110 such that the substrate 400 is again carried by the carrier tray 500. Please refer to FIGS. 24a to 24b, which are schematic diagrams illustrating a process of the first transferring mechanism lifting the carrier tray. The first transferring mechanism 110 activates the vacuum nozzles 111 corresponding to the location of the carrier tray 500 to lift the carrier tray 500 upward, such that the carrier tray 500 contacts the substrate 400 again, allowing the substrate 400 to be again carried (supported) by the carrier tray 500.

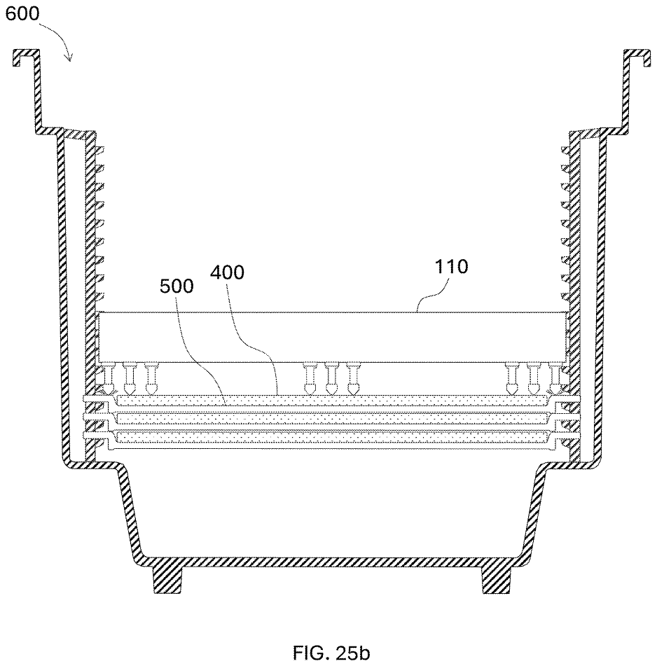

In step S187, the carrier tray 500 and the substrate 400 carried thereon are transferred together from the substrate transferring platform 230 into the first-type container 600 by the first transferring mechanism 110. Please refer to FIGS. 25a to 25b, which are schematic diagrams illustrating a process of the first transferring mechanism transferring the substrate and the carrier tray into the first-type container. The first transferring mechanism 110 transfers the carrier tray 500 and the substrate 400 carried thereon together back into the first-type container 600, such that the substrate 400 and the carrier tray 500 are restacked in the first-type container 600.

The substrate transferring system and method according to the embodiments of the present invention transfer at least the substrate onto the substrate transferring platform by means of the first transferring mechanism and then transfer the substrate from the substrate transferring platform into the second-type container by means of the second transferring mechanism, thereby achieving fast, efficient, and safe substrate transferring. As a result, the problems of conventional manual transferring, which consumes massive labor and time and reduces overall process efficiency, are improved. Moreover, the risk of damaging the substrate caused by the transferring process can also be significantly reduced.

Although the present invention has been disclosed with a number of embodiments as above, they are not intended to limit the present invention. Any person skilled in the art can make various modifications and refinements without departing from the spirit and scope of the present invention. Therefore, the protection scope of the present invention shall be defined by the scope of the appended claims.

What is claimed is:

1. A substrate transferring system for transferring a substrate between a first-type container and a second-type container, the substrate transferring system comprising:
a first transferring mechanism disposed adjacent to the first-type container and configured to pick and place the substrate and/or a carrier tray carrying the substrate from and into the first-type container;
a second transferring mechanism disposed adjacent to the second-type container and configured to pick and place the substrate from and into the second-type container; and
a substrate transferring platform disposed between the first transferring mechanism and the second transferring mechanism and configured to receive at least the substrate to facilitate a handover of the substrate between the first transferring mechanism and the second transferring mechanism.

2. The substrate transferring system according to claim 1, wherein the first transferring mechanism is configured to transfer the substrate and/or the carrier tray between the substrate transferring platform and the first-type container, and the second transferring mechanism is configured to transfer the substrate between the substrate transferring platform and the second-type container.

3. The substrate transferring system according to claim 1, wherein the substrate transferring platform is further configured to separate the substrate from the carrier tray to support the substrate above the carrier tray.

4. The substrate transferring system according to claim 3, wherein the first transferring mechanism is configured to lift the carrier tray such that the substrate is again carried by the carrier tray, thereby allowing the substrate and the carrier tray to be transferred together to the first-type container.

5. The substrate transferring system according to claim 1, wherein the substrate transferring platform comprises:
a frame body; and
a plurality of alignment units pivotally connected to the frame body and pivotable between an open state and an alignment state, wherein the alignment units define an alignment area when in the alignment state;
wherein the first transferring mechanism is configured to transfer the substrate into the alignment area.

6. The substrate transferring system according to claim 1, further comprising:
a tray placement platform configured to receive the carrier tray, wherein the first transferring mechanism is configured to transfer the carrier tray from the tray placement platform to the first-type container or the substrate transferring platform.

7. A substrate transferring method for transferring a substrate between a first-type container and a second-type container, the substrate transferring method comprising:
picking or placing, by a first transferring mechanism, the substrate and/or a carrier tray carrying the substrate from or into the first-type container;
receiving at least the substrate, by a substrate transferring platform, to facilitate a handover of the substrate between the first transferring mechanism and a second transferring mechanism; and
picking or placing, by the second transferring mechanism, the substrate from or into the second-type container.

8. A substrate transferring method for transferring a substrate between a first-type container and a second-type container, the substrate transferring method comprising:
transferring, by a first transferring mechanism, the substrate and/or a carrier tray carrying the substrate from the first-type container to a substrate transferring platform; and
transferring, by a second transferring mechanism, the substrate from the substrate transferring platform to the second-type container.

9. The substrate transferring method according to claim 8, further comprising:
transferring, by the second transferring mechanism, the substrate from the second-type container to the substrate transferring platform; and
transferring, by the first transferring mechanism, at least the substrate from the substrate transferring platform to the first-type container.

10. The substrate transferring method according to claim 8, wherein the substrate and the carrier tray are transferred together by the first transferring mechanism from the first-type container to the substrate transferring platform, and after the substrate and the carrier tray are transferred together to the substrate transferring platform, the substrate transferring method further comprises:
separating, by the substrate transferring platform, the substrate from the carrier tray to support the substrate above the carrier tray.
